(19) United States
(12) Patent Application Publication
(10) Pub. No.: US 2022/0407036 A1
(43) Pub. Date: Dec. 22, 2022

(54) DISPLAY PANEL, METHOD OF MANUFACTURING THEREOF, AND DISPLAY DEVICE

(71) Applicant: SHENZHEN CHINA STAR OPTOELECTRONICS SEMICONDUCTOR DISPLAY TECHNOLOGY CO., LTD., Shenzhen, Guangdong (CN)

(72) Inventors: Lixuan CHEN, Shenzhen, Guangdong (CN); Weiran CAO, Shenzhen, Guangdong (CN)

(73) Assignee: SHENZHEN CHINA STAR OPTOELECTRONICS SEMICONDUCTOR DISPLAY TECHNOLOGY CO., LTD., Shenzhen, Guangdong (CN)

(21) Appl. No.: 17/255,490

(22) PCT Filed: Dec. 18, 2020
(86) PCT No.: PCT/CN2020/137519

§ 371 Date: Dec. 23, 2020

(30) Foreign Application Priority Data
Dec. 2, 2020 (CN) 202011402659.1

(51) Int. Cl. H01L 51/52; H01L 51/56

(52) U.S. Cl. CPC H01L 51/5268; H01L 51/5253; H01L 51/56; H01L 27/3246

(57) ABSTRACT

A display panel, an array substrate, an organic light-emitting diode (OLED) functional layer, a packaging layer, a filling layer, a protective layer, an edge packaging glue, and nanoparticles are provided. The nanoparticles are uniformly provided in the filling layer or the protective layer of the panel, and the nanoparticles can effectively increase the light diffusion effect, so the viewing angle of the display panel can be effectively improved.

### BACKGROUND OF INVENTION

### Field of Invention

The present invention relates to a field of display technology, and more particularly, to a display panel, a method of manufacturing thereof, and a display device.

### Description of Prior Art

Organic light-emitting diode (OLED) display panels have advantages of high color gamut, good viewing angles, and fast response times, but they also have some defects on their own. For example, brightness of the OLED display panels is low, and their stability is slightly worse than other displays. On the other hand, for OLED devices manufactured by inkjet printing technology (IJP), there is also a risk of color casting in in the devices due to microcavity effect of IJP OLED sub-pixel light-emitting devices.

In order to improve viewing angles and brightness of OLED display panels, many methods have been proposed, such as adding optical microstructures, such as microlens arrays, gratings, etc., on the light exit interface of the display panels, or adding a refractive index matching layer between the light exit interfaces. Although these methods have a certain effect, the feasibility of mass production is not high.

Therefore, it is necessary to provide a new display panel to solve the viewing angle and brightness problems in the prior art.

### SUMMARY OF INVENTION

The first object of the present invention is to provide a display panel, which can effectively increase the light diffusion effect, and thus can effectively improve the viewing angles of the display panel.

In one embodiment, a display panel comprises an array substrate comprising a display area and a non-display area, and the non-display area surrounds the display area; an organic light-emitting diode (OLED) functional layer disposed in the display area of the array substrate; a packaging layer disposed on the OLED functional layer; a filling layer disposed on the packaging layer; a protective layer disposed on the filling layer; and a plurality of nanoparticles uniformly arranged in the filling layer or the protective layer.

In one embodiment, the display panel further comprises an edge packaging glue filled between the non-display area of the array substrate and the protective layer.

In one embodiment, material of the filling layer comprises a resin or a glue.

In one embodiment, the plurality of nanoparticles are spherical structures, and a diameter of the nanoparticles ranges from 50 nm to 1000 nm.

In one embodiment, a thickness of the filling layer ranges from 5 μm to 8 μm.

In one embodiment, the plurality of nanoparticles comprise TiO₂.

In one embodiment, a refractive index of the filling layer is greater than or equal to 2.

In one embodiment, a material of the protective layer comprises a glass or an organic film.

The second object of the present invention is to provide a method of manufacturing a display panel, and the method comprises: providing an array substrate comprising a display area and a non-display area, and the non-display area surrounds the display area; forming an organic light-emitting diode (OLED) functional layer, a packaging layer, a filling layer, and a protective layer above the display area of the array substrate in order, and the filling layer or the protective layer comprises a plurality of nanoparticles; and filling an edge packaging glue between the non-display area of the array substrate and the protective layer.

The second object of the present invention is to provide a display device comprising the above-mentioned display panel.

The present invention has beneficial effects described herein. The present invention provides a display panel, a method of manufacturing thereof, and a display device. By uniformly disposing nanoparticles in the filling layer or protective layer of the panel, the nanoparticles can effectively increase the light diffusion effect, so the viewing angle of the display panel can be effectively improved.

### BRIEF DESCRIPTION OF DRAWINGS

The following detailed description of the specific implementations of the present application in conjunction with the accompanying drawings will make the technical solutions and other beneficial effects of the present application obvious.

FIG. 1 is a schematic structural view of a display panel according to one embodiment of the present invention.

FIG. 2 is a structural schematic view of an array substrate according to one embodiment of the present invention.

FIG. 3 is a structural schematic view of an organic light-emitting diode (OLED) functional layer according to one embodiment of the present invention.

FIG. 4 is a structural schematic view of a packaging layer according to one embodiment of the present invention.

Reference Numerals:

display panel 300; array substrate 100; organic light-emitting diode (OLED) functional layer 200; packaging layer 201; filling layer 202; protective layer 203; edge packaging glue 204; substrate 101; active layer 102; first insulating layer 103; gate 104; second insulating layer 105; metal layer 106; interlayer insulating layer 107; source-drain metal layer 108; planarization layer 109; first electrode 110; pixel defining layer 111; first inorganic layer 2011; organic layer 2021; second inorganic layer 2031; display area 1101; non-display area 1102; hole injection layer 211; hole transport layer 212; light-emitting layer 213; electron transport layer 214; electron injection layer 215; cathode 216.

### DETAILED DESCRIPTION OF PREFERRED EMBODIMENTS

The specific structure and functional details disclosed herein are only representative, and are used for the purpose of describing exemplary embodiments of the present application. However, this application can be implemented in many alternative forms, and should not be interpreted as being limited only to the embodiments set forth herein.

In the description of this application, it should be understood that the terms “center”, “lateral”, “upper”, “lower”, “left”, “right”, “vertical”, “horizontal”, “top”, “bottom”, “inner”, and “outer” etc., indicated as orientation or positional relationship are based on the orientation or positional relationship shown in the drawings, they merely intend to illustrate the present invention and simplify the description, but are not to be as indicating or implying specific devices or elements having specific orientation, specific orientation structure and operating. Therefore, it cannot be understood as limitations. Moreover, the terms “first” and “second” are merely used for describing purposes, but are not to be conceived as indicating or implying a relative important or implicitly indicating specific technical feature numbers. Accordingly, the feature limitations of “first” or “second” may include one or more of the described features explicitly or implicitly. In the description of the present invention, the meaning of “a plurality of” is two or more, unless otherwise explicitly defined.

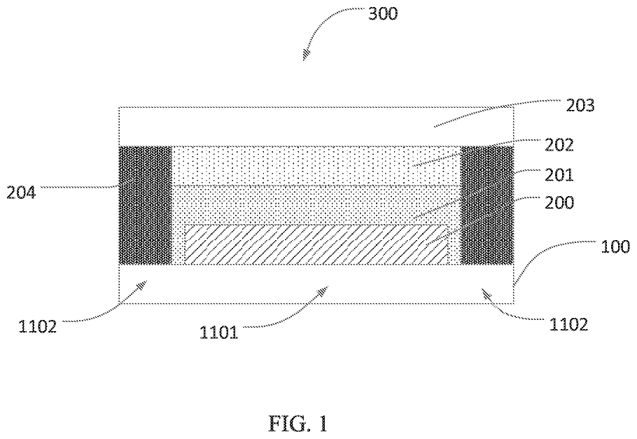

As shown in FIG. 1, a display panel 300 is provided and includes an array substrate 100, an organic light-emitting diode (OLED) functional layer 200, a packaging layer 201, a filling layer 202, a protective layer 203, an edge packaging glue 204, and a plurality of nanoparticles.

The array substrate 100 includes a display area 1101 and a non-display area 1102, and the non-display area 1102 surrounds the display area 1101.

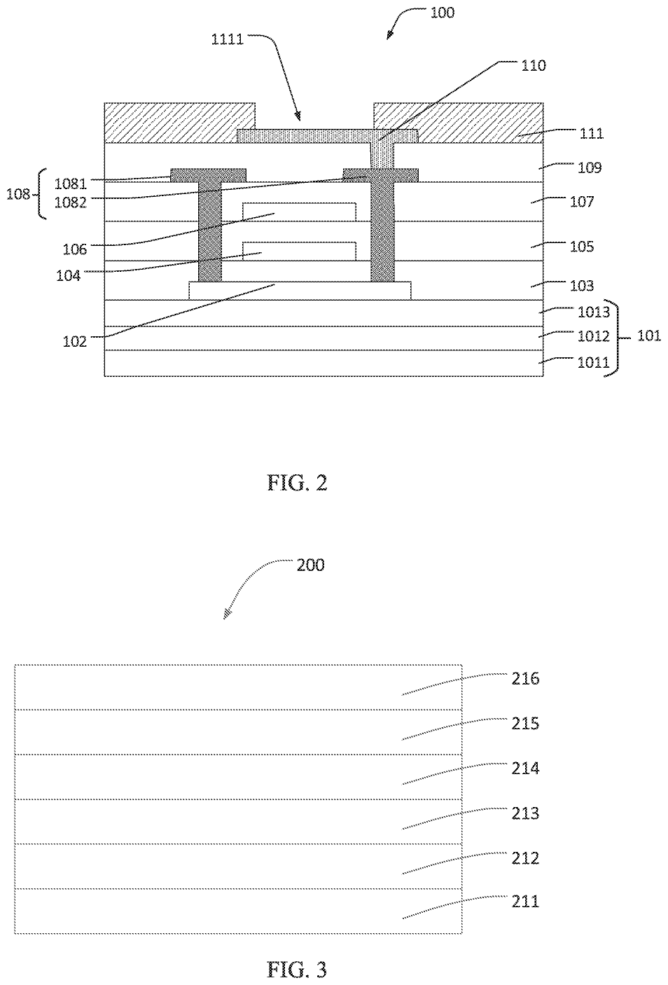

As shown in FIG. 2, in one embodiment, the array substrate 100 includes: a substrate 101, an active layer 102, a first insulating layer 103, a gate 104, a second insulating layer 105, a metal layer 106, an interlayer insulating layer 107, a source-drain metal layer 108, a planarization layer 109, a first electrode 110, and a pixel defining layer 111.

Continuing to refer to FIG. 2, the substrate 101 includes a glass substrate 1011, a barrier layer 1012 and a buffer layer 1013.

The barrier layer 1012 is disposed on the glass substrate 1011. The buffer layer 1013 is disposed on a side of the barrier layer 1012 away from the glass substrate 1011. The material of the barrier layer 1012 includes silicon nitride and silicon oxide.

The active layer 102 is disposed on the substrate 101. The active layer 102 is made of polysilicon.

The first insulating layer 103 is disposed on the active layer 102 and the substrate 101. The gate 104 is disposed on the first insulating layer 103. The material of the gate 104 includes aluminum, copper, and copper-aluminum alloy. That is, the material of the gate 104 may be selected from aluminum, copper, or a copper-aluminum alloy.

Among them, aluminum has the best electrical conductivity, and aluminum and copper have better flexibility, and are suitable for manufacturing the flexible display panel 300.

In the present invention, the gate 104 of the display panel 300 is made of copper-aluminum alloy, and its conductivity and bending resistance are far superior to the molybdenum used as currently gate material, and can be well suited for folding display panels or flexible display panels.

The second insulating layer 105 is disposed on the gate 104 and the first insulating layer 103.

The metal layer 106 is disposed on the second insulating layer 105.

The interlayer insulating layer 107 is disposed on the metal layer 106 and the second insulating layer 105.

The source-drain metal layer 108 is disposed on the interlayer insulating layer 107 and connected to the active layer 102. The source-drain metal layer 108 includes a source trace 1081 and a drain trace 1082, and the source trace 1081 and the drain trace 1082 are connected to the active layer 102.

The planarization layer 109 is disposed on the source-drain metal layer 108 and the interlayer insulating layer 107. The first electrode 110 is disposed on the planarization layer 109.

The pixel defining layer 111 is disposed on the first electrode 110 and the planarization layer 109. The pixel defining layer 111 has a groove 1111.

The first electrode 110 is exposed in the groove 1111. The first electrode 110 is connected to the source-drain metal layer 108. The first electrode 110 is an anode.

The OLED functional layer 200 is disposed on the display area 1101 of the array substrate 100. Specifically, the OLED functional layer 200 is disposed on the first electrode 110.

As shown in FIG. 3, the OLED functional layer 200 includes a hole injection layer 211, a hole transport layer 212, a light-emitting layer 213, an electron transport layer 214, an electron injection layer 215, and a cathode 216.

The hole transport layer 212 is disposed on the hole injection layer 211. The light-emitting layer 213 is disposed on the hole transport layer 212. The electron transport layer 214 is disposed on the light-emitting layer 213. The electron injection layer 215 is disposed on the electron transport layer 214. The cathode 216 is disposed on the electron injection layer 215.

The packaging layer 201 is disposed on the OLED functional layer 200.

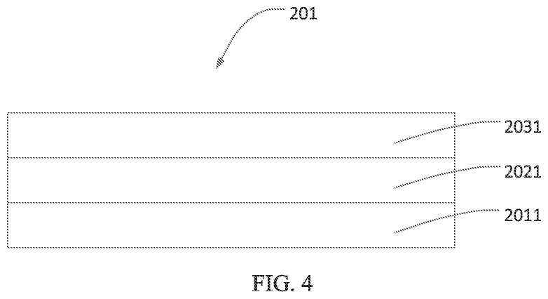

As shown in FIG. 4, the packaging layer 201 is a repeating laminated structure, and each repeating unit includes: a first inorganic layer, an organic layer, and a second inorganic layer.

The material of the first inorganic layer includes silicon oxide or silicon nitride.

The organic layer is disposed on the first inorganic layer, and the material of the organic layer includes polyimide.

The second inorganic layer is disposed on the organic layer. The material of the second inorganic layer includes silicon oxide or silicon nitride.

The filling layer 202 is disposed on the packaging layer 201. The material of the filling layer 202 includes: a resin or a glue.

A thickness of the filling layer 202 ranges from 5 μm to 8 μm, preferably 5 μm. A refractive index of the filling layer 202 is greater than or equal to 2 when the filling layer 202 has a thickness of 550 nm.

The protective layer 203 is disposed on the filling layer 202. The material of the protective layer 203 includes: a glass or an organic film. In a general flexible device, a thickness of the packaged protective layer 203 also ranges from a few micrometers to hundreds of micrometers.

The plurality of nanoparticles are uniformly arranged in the filling layer 202 or the protective layer 203. A diameter of the nanoparticles ranges from 50 nm to 1000 nm.

The plurality of nanoparticles are spherical structures, and the nanoparticles include TiO₂.

An edge packaging glue 204 is filled between the non-display area 1102 of the array substrate 100 and the protective layer 203. The edge packaging glue 204 surrounds the display area 1101.

The present invention provides a display panel 300, by uniformly disposing nanoparticles in the filling layer 202 or the protective layer 203 of the panel, the nanoparticles can effectively increase the light diffusion effect, thereby effectively improving the viewing angle of the display panel 300.

The present invention further provides a method of manufacturing a display panel, and the method includes following step S1 to step S3.

Step S1, providing an array substrate 100 comprising a display area 1101 and a non-display area 1102. The non-display area 1102 surrounds the display area 1101.

Step S2, forming an organic light-emitting diode (OLED) functional layer 200, a packaging layer 201, a filling layer 202, and a protective layer 203 above the display area 1101 of the array substrate 100 in order. The filling layer 202 or the protective layer 203 includes a plurality of nanoparticles.

Step S3, filling an edge packaging glue 204 between the non-display area 1102 of the array substrate 100 and the protective layer 203.

In the present invention, nanoparticles are uniformly arranged in the filling layer 202 or the protective layer 203 of the panel, and the nanoparticles can effectively increase the light diffusion effect, thereby effectively improving the viewing angle of the display panel 300.

The present invention further provides a display device including the above-mentioned display panel 300. In the display device, nanoparticles are uniformly arranged in the filling layer 202 or the protective layer 203 of the panel, and the nanoparticles can effectively increase the light diffusion effect, thereby effectively improving the viewing angle of the display panel 300.

In the above, the present application has been described in the above preferred embodiments, but the preferred embodiments are not intended to limit the scope of the invention, and a person skilled in the art may make various modifications without departing from the spirit and scope of the application. The scope of the present application is determined by claims.

What is claimed is:

1. A display panel, comprising:
an array substrate comprising a display area and a non-display area, wherein the non-display area surrounds the display area;
an organic light-emitting diode (OLED) functional layer disposed in the display area of the array substrate;
a packaging layer disposed on the OLED functional layer;
a filling layer disposed on the packaging layer;
a protective layer disposed on the filling layer; and
a plurality of nanoparticles uniformly arranged in the filling layer or the protective layer.

2. The display panel according to claim 1, further comprising an edge packaging glue filled between the non-display area of the array substrate and the protective layer.

3. The display panel according to claim 1, wherein material of the filling layer comprises a resin or a glue.

4. The display panel according to claim 1, wherein the plurality of nanoparticles are spherical structures, and a diameter of the nanoparticles ranges from 50 nm to 1000 nm.

5. The display panel according to claim 1, wherein a thickness of the filling layer ranges from 5 μm to 8 μm.

6. The display panel according to claim 1, wherein the plurality of nanoparticles comprise TiO₂.

7. The display panel according to claim 1, wherein a refractive index of the filling layer is greater than or equal to 2.

8. The display panel according to claim 1, wherein a material of the protective layer comprises a glass or an organic film.

9. A method of manufacturing a display panel, comprising:
providing an array substrate comprising a display area and a non-display area, wherein the non-display area surrounds the display area;
forming an organic light-emitting diode (OLED) functional layer, a packaging layer, a filling layer, and a protective layer above the display area of the array substrate in order, wherein the filling layer or the protective layer comprises a plurality of nanoparticles; and
filling an edge packaging glue between the non-display area of the array substrate and the protective layer.

10. A display device, comprising:
a display panel, wherein the display panel comprises:
an array substrate comprising a display area and a non-display area, wherein the non-display area surrounds the display area;
an organic light-emitting diode (OLED) functional layer disposed in the display area of the array substrate;
a packaging layer disposed on the OLED functional layer;
a filling layer disposed on the packaging layer;
a protective layer disposed on the filling layer; and
a plurality of nanoparticles uniformly arranged in the filling layer or the protective layer.

11. The display device according to claim 10, wherein the display panel further comprises an edge packaging glue filled between the non-display area of the array substrate and the protective layer.

12. The display device according to claim 10, wherein material of the filling layer comprises a resin or a glue.

13. The display device according to claim 10, wherein the plurality of nanoparticles are spherical structures, and a diameter of the nanoparticles ranges from 50 nm to 1000 nm.

14. The display device according to claim 10, wherein a thickness of the filling layer ranges from 5 μm to 8 μm.

15. The display device according to claim 10, wherein the plurality of nanoparticles comprise TiO₂.

16. The display device according to claim 10, wherein a refractive index of the filling layer is greater than or equal to 2.

17. The display device according to claim 10, wherein a material of the protective layer comprises a glass or an organic film.
